(19) United States
(12) Patent Application Publication
(10) Pub. No.: US 2026/0018203 A1
(43) Pub. Date: Jan. 15, 2026

(54) MEMORY DEVICE, OPERATING METHOD OF MEMORY DEVICE AND MEMORY SYSTEM

(71) Applicant: SAMSUNG ELECTRONICS CO., LTD., Suwon-si (KR)

(72) Inventors: Yong Sun KIM, Suwon-si (KR); Dae Hyun KIM, Suwon-si (KR)

(73) Assignee: SAMSUNG ELECTRONICS CO., LTD., Suwon-si (KR)

(21) Appl. No.: 19/169,457

(22) Filed: Apr. 3, 2025

(30) Foreign Application Priority Data
Jul. 9, 2024 (KR) 10-2024-0090744

(51) Int. Cl. G11C 11/4072; G11C 11/4074; G11C 11/4076

(52) U.S. Cl. CPC G11C 11/4072; G11C 11/4074; G11C 11/4076

(57) ABSTRACT

Provided is a memory device and a method of operating same, the memory device including: a mode register configured to store a first setting value corresponding to a power-down operation to be performed in a power-down state and a second setting value corresponding to a start time of a power gating operation; and a power-down control circuit, wherein the power-down control circuit is configured to: control the memory device to perform the power-down operation based on a first command for causing the memory device to enter the power-down state, and based on the power-down operation comprising the power gating operation, control the memory device to perform the power gating operation at the start time after the memory device enters the power-down state.

### CROSS-REFERENCE TO RELATED APPLICATIONS

This application claims priority to Korean Patent Application No. 10-2024-0090744, filed on Jul. 9, 2024 in the Korean Intellectual Property Office, the disclosure of which is incorporated by reference herein in its entirety.

### BACKGROUND

### 1. Field

The present disclosure relates to a memory device, an operating method of the memory device, and a memory system. More particularly, the present disclosure relates to an operating method of a memory device performing a power-down operation and a memory system.

### 2. Description of Related Art

A memory device is used to store data and may be classified as a volatile memory device or a nonvolatile memory device. A volatile memory device refers to a memory device which loses data stored therein when a power is turned off. A dynamic random access memory (DRAM), among volatile memory devices, is used in various fields such as mobile systems, servers, and graphics devices.

To reduce power consumption of DRAM, DRAM provides a low-power mode such as a power-down mode or a self-refresh mode. In the low-power mode, in general, DRAM performs the power-down operation in compliance with an internally defined fixed rule.

However, because the power-down operation of DRAM for minimizing power consumption of a system differs depending on the system, there is a limitation in optimizing a system power through the above conventional way to perform the power-down operation.

### SUMMARY

Provided is a memory device capable of optimizing a system power by controlling a power-down operation, an operating method of the memory device, and a memory system.

According to an aspect of the disclosure, a memory device includes: a mode register configured to store a first setting value corresponding to a power-down operation to be performed in a power-down state and a second setting value corresponding to a start time of a power gating operation; and a power-down control circuit, wherein the power-down control circuit is configured to: control the memory device to perform the power-down operation based on a first command for causing the memory device to enter the power-down state, and based on the power-down operation comprising the power gating operation, control the memory device to perform the power gating operation at the start time after the memory device enters the power-down state.

According to an aspect of the disclosure, a method of operating a memory device includes: storing, in a mode register of the memory device, a first setting value corresponding to a power-down operation to be performed in a power-down state and a second setting value corresponding to a start time of a power gating operation; and based on the memory device entering the power-down state, performing the power-down operation based on the first and the second setting values, wherein the performing of the power-down operation comprises: based on the power-down operation corresponding to the first setting value comprising the power gating operation, performing the power gating operation at the start time after the memory device enters the power-down state.

According to an aspect of the disclosure, a memory system includes: a memory controller configured to transmit a mode register write command comprising a first setting value corresponding to a power-down operation and a second setting value corresponding to a start time of a power gating operation; and a memory device comprising a mode register, wherein the memory device is configured to: set the first setting value and the second setting value in the mode register based on the mode register write command, to perform a power-down operation corresponding to the first setting value when a power-down entry command is received from the memory controller, and based on the power-down operation comprising the power gating operation, perform the power gating operation at the start time after the memory device enters a power-down state.

### BRIEF DESCRIPTION OF DRAWINGS

The above and other aspects and features of certain embodiments of the present disclosure will be more apparent from the following description taken in conjunction with the accompanying drawings, in which:

FIG. 1 is a block diagram of a memory system according to one or more embodiments of the present disclosure;

FIG. 2 is a diagram for describing power consumption according to whether a power gating operation is performed;

FIG. 3 is a table illustrating mode register information according to one or more embodiments of the present disclosure;

FIG. 4 is a block diagram for describing an operation of a memory device according to one or more embodiments of the present disclosure;

FIG. 5 is a block diagram of a power-down control circuit according to one or more embodiments of the present disclosure;

FIG. 6A is an operation timing diagram of a counter according to one or more embodiments of the present disclosure;

FIG. 6B is an operation timing diagram of a multiplexer according to one or

more embodiments of the present disclosure;

FIG. 7 is a diagram illustrating an example in which a start time of a power gating operation is applied to a control signal for a power gating operation;

FIG. 8 is a diagram for describing a power-down operation according to one or more embodiments of the present disclosure;

FIG. 9 is a diagram for describing a power-down operation according to one or more embodiments of the present disclosure;

FIG. 10 is a diagram for describing a power-down operation according to one or more embodiments of the present disclosure;

FIG. 11 is a diagram for describing a power-down operation according to one or more embodiments of the present disclosure;

FIG. 12 is a diagram illustrating examples of a first command according to one or more embodiments of the present disclosure;

FIG. 13 is a diagram illustrating examples of a first command according to one or more embodiments of the present disclosure;

FIG. 14 is a block diagram for describing an operation of a memory device according to one or more embodiments of the present disclosure;

FIG. 15 is a block diagram for describing an operation of a memory device according to one or more embodiments of the present disclosure;

FIG. 16 is a diagram illustrating power gating switches according to one or more embodiments of the present disclosure;

FIG. 17 is a flowchart illustrating an operating method a memory device according to one or more embodiments of the present disclosure; and

FIG. 18 is a flowchart illustrating an operating method a memory device according to one or more embodiments of the present disclosure.

### DETAILED DESCRIPTION

Hereinafter, one or more embodiments of the present disclosure will be described in detail with reference to the accompanying drawings to such an extent that one skilled in the art to which the present disclosure belongs may practice the present disclosure.

In the present disclosure, the expressions “first”, “second”, etc. may modify various components regardless of the order and/or the importance, are only used to distinguish one component from another component, and are not intended to limit the order or importance of components.

In the following description, like reference numerals refer to like elements throughout the specification. Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

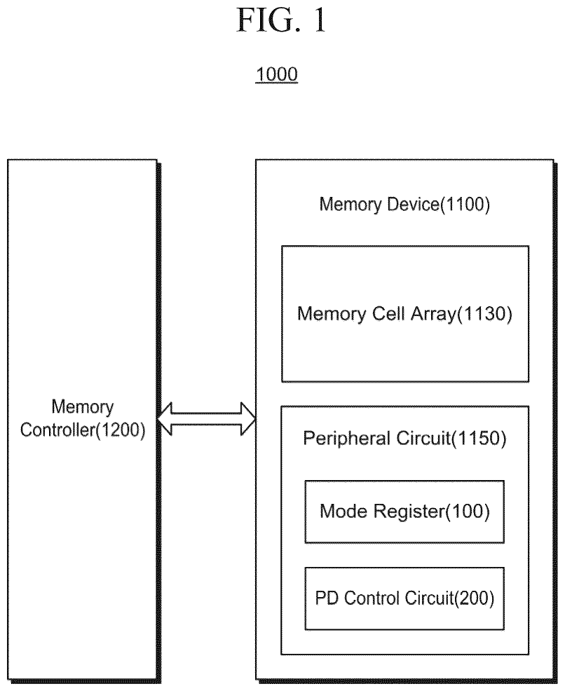

FIG. 1 is a block diagram illustrating a configuration of a memory system according to one or more embodiments of the present disclosure.

According to one or more embodiments of the present disclosure, a memory controller 1200 may control a power-down operation of a memory device 1100.

For example, the memory controller 1200 may transmit information associated with the power-down operation to the memory device 1100. In one or more embodiments, the information associated with the power-down operation may include at least one of information about the power-down operation to be performed by the memory device 1100 in a power-down state and information about a start time of a power gating operation.

The memory device 1100 may perform the power-down operation based on the information associated with the power-down operation, which is received from the memory controller 1200. For example, the memory device 1100 may store the received information associated with the receive power-down operation in a mode register 100. Afterwards, when the memory device 1100 enters the power-down state, the memory device 1100 may perform the power-down operation based on the information stored in the mode register 100.

According to the above description, the memory controller 1200 may variously control the power-down operation of the memory device 1100 by using the mode register 100 of the memory device 1100. Accordingly, power optimization of a memory system 1000 may be accomplished.

Referring to FIG. 1, the memory system 1000 may include the memory controller 1200 and the memory device 1100.

The memory controller 1200 may control the memory device 1100. For example, the memory controller 1200 may control the memory device 1100 depending on a request of a processor supporting various applications such as a server application, a personal computer (PC) application, and a mobile application. For example, the memory controller 1200 may be included in a host device (e.g., a system on chip (SoC)) including a processor and may control the memory device 1100 depending on a request of the processor.

To control the memory device 1100, the memory controller 1200 may transmit a command and/or an address to the memory device 1100. Also, the memory controller 1200 may transmit data to the memory device 1100 or may receive data from the memory device 1100.

In particular, the memory controller 1200 may control the power-down operation of the memory device 1100.

To this end, the memory controller 1200 may transmit to the memory device 1100 a command (hereinafter referred to as a “first command”) which allows the memory device 1100 to enter the power-down state or a command (hereinafter referred to as a “second command”) which allows the memory device 1100 to exit from the power-down state. According to one or more embodiments, the first command may be a power down entry (PDE) command, and the second command may be a power down exit (PDX) command. However, the present disclosure is not limited thereto. The memory device 1100 may enter the power-down state when the first command is received and may exit from the power-down state when the second command is received.

Also, the memory controller 1200 may transmit, to the memory device 1100, a command (hereinafter referred to as a “third command”) including a first setting value corresponding to the power-down operation to be performed by the memory device 1100 in the power-down state and a second setting value corresponding to a start time of the power gating operation. In this case, the first setting value may have a value corresponding to one power-down operation selected from a plurality of power-down operations determined in advance, and the second setting value may have a value corresponding to one start time selected from a plurality of start times determined in advance in association with the power gating operation. The third command may be, but is not limited to, a mode register write (MRW) command or a mode register set (MRS) command. When the third command is received, the memory device 1100 may set or store the first setting value and the second setting value in the mode register 100.

The memory device 1100 may receive data from the memory controller 1200 and may store the received data. In response to a request of the memory controller 1200, the memory device 1100 may read the stored data and may transmit the read data to the memory controller 1200.

In one or more embodiments, the memory device 1100 may be a memory device including volatile memory cells. For example, the memory device 1100 may include various dynamic random access memory (DRAM) devices such as a double data rate synchronous DRAM (DDR SDRAM), a DDR2 SDRAM, a DDR3 SDRAM, a DDR4 SDRAM, a DDR5 SDRAM, a DDR6 SDRAM, a low power double data rate (LPDDR) SDRAM, an LPDDR2 SDRAM, an LPDDR2 SDRAM, an LPDDR3 SDRAM, an LPDDR4 SDRAM, an LPDDR4X SDRAM, an LPDDR5 SDRAM, a graphics double data rate synchronous graphics random access memory (GDDR SGRAM), a GDDR2 SGRAM, a GDDR3 SGRAM, a GDDR4 SGRAM, a GDDR5 SGRAM, and a GDDR6 SGRAM.

Also, in one or more embodiments, the memory device 1100 may be a stacked memory device, in which DRAM dies are stacked, such as a high bandwidth memory (HBM), an HBM2, or an HBM3.

In addition, in one or more embodiments, the memory device 1100 may be a memory module such as a dual in-line memory module (DIMM). For example, the memory device 1100 may be a registered DIMM (RDIMM), a load reduced DIMM (LRDIMM), an unbuffered DIMM (UDIMM), a fully buffered DIMM (FB-DIMM), or a small outline DIMM (SO-DIMM). However, the foregoing are provided only as examples, and the memory device 1100 may be any other memory module such as a single in-line memory module (SIMM).

Also, in one or more embodiments, the memory device 1100 may be an SRAM device, a NAND flash memory device, a NOR flash memory device, an RRAM device, an FRAM device, a PRAM device, a TRAM device, an MRAM device, etc.

The memory device 1100 may include a memory cell array 1130 and a peripheral circuit 1150. The memory cell array 1130 may include a plurality of banks. Each of the plurality of banks may include memory cells for storing data. For convenience of description, in the specification, it is assumed that each bank includes DRAM cells. However, this is provided as an example, and each of the plurality of banks may be implemented to include any other volatile memory cells in addition to the DRAM cells. Also, the plurality of banks may be implemented to include the same kind of memory cells or may be implemented to include different kinds of memory cells.

The plurality of memory cells included in each bank may be disposed at intersections of a plurality of rows and a plurality of columns to constitute an array in the form of a matrix. Accordingly, each bank may include a plurality of cell rows or a plurality of cell columns. In this case, memory cells belonging to the same cell row may be connected to the same word line, and memory cells belonging to the same cell column may be connected to the same bit line. However, the present disclosure is not limited thereto.

The peripheral circuit 1150 may drive the memory cell array 1130. The peripheral circuit 1150 may include various kinds of analog circuits and digital circuits which are necessary to store data in the memory cell array 1130 or to read data stored in the memory cell array 1130.

Various kinds of circuits included in the peripheral circuit 1150 may be classified into a plurality of function blocks depending on functions to be performed. For example, the plurality of function blocks included in the peripheral circuit 1150 may include, but are not limited to, a sense amplifier, a row decoder (or an X-decoder), a column decoder (or a Y-decoder), a command decoder, an address decoder, an address register, an address latch, a bank control circuit, a refresh control circuit, an ECC engine, an input/output buffer, a power circuit (i.e., a DC circuit), an oscillator, etc.

According to one or more embodiments of the present disclosure, the peripheral circuit 1150 may include the mode register 100 and a power-down control circuit 200.

The mode register 100 may store information associated with the power-down operation of the memory device 1100. For example, the mode register 100 may store the first setting value corresponding to the power-down operation to be performed in the power-down state and the second setting value corresponding to the start time of the power gating operation. For example, the first setting value and the second setting value may be stored in the mode register 100 based on the third command received from the memory controller 1200.

The power-down control circuit 200 may control the memory device 1100 to perform the power-down operation based on the first setting value and the second setting value.

For example, when the first command is received from the memory controller 1200, the memory device 1100 may enter the power-down state. When the memory device 1100 enters the power-down state, the power-down control circuit 200 may control the memory device 1100 to perform the power-down operation based on the first setting value.

In this case, the power-down control circuit 200 may differently control the memory device 1100 depending on whether the power-down operation corresponding to the first setting value includes the power gating operation. For example, when the power-down operation corresponding to the first setting value includes the power gating operation, the power-down control circuit 200 may control the memory device 1100 to perform the power gating operation at the start time corresponding to the second setting value after entering the power-down state. Also, when the power-down operation corresponding to the first setting value does not include the power gating operation, the power-down control circuit 200 may ignore the second setting value.

In one or more embodiments, the power-down operation corresponding to the first setting value may be an operation of turning off an input/output buffer. In this case, the power-down control circuit 200 may turn off the input/output buffer and may ignore the second setting value.

Also, in one or more embodiments, the power-down operation corresponding to the first setting value may include the operation of turning off the input/output buffer and the power gating operation. In this case, the power-down control circuit 200 may turn off the input/output buffer and may block an external power, which function blocks targeted for the power gating operation, at the start time corresponding to the second setting value.

According to the above embodiments of the present disclosure, the memory controller 1200 may control contents of the power-down operation to be performed by the memory device 1100 in the power-down state. Also, the memory controller 1200 may control the start time of the power-gating operation to be performed by the memory device 1100 in the power-down state. Accordingly, power optimization of a memory system 1000 may be accomplished.

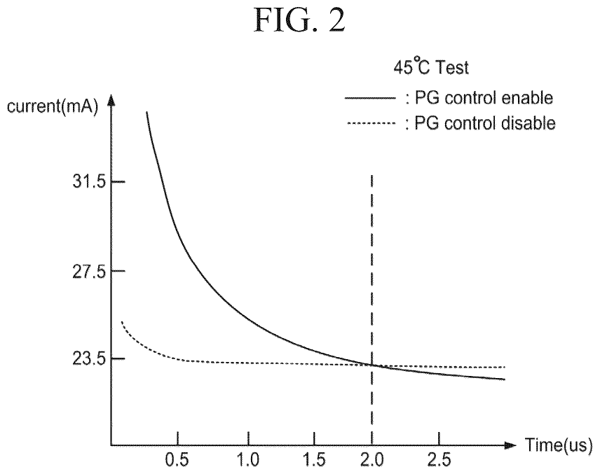

FIG. 2 is a graph illustrating a power consumption amount of a memory device according to whether a power gating operation is performed after entering a power-down state. In FIG. 2, the solid line indicates the case of entering the power-down state while simultaneously performing the power gating operation, and the dotted line indicates the case of entering the power-down state without the execution of the power gating operation.

The power gating operation refers to an operation of turning off one or more power gating switches connected between one or more target function blocks and the external power and/or between the one or more target function blocks and a ground such that the external power being provided to the corresponding function blocks is blocked. Power necessary to turn off the power gating switch in the power gating operation is consumed during the power gating operation.

Referring to FIG. 2, it may be understood that the amount of current which is consumed when the power gating operation is not performed until 2 μs after entering the power-down state is smaller than the amount of current which is consumed when the power gating operation is performed until 2 μs after entering the power-down state. That is, the case where a time during which the memory device remains in the power-down state is shorter than a specific time (2 μs in the example of FIG. 2) is called a “short power-down,” and the case where a time during which the memory device remains in the power-down state is longer than the specific time is called a “long power-down.” Generally, it may be more advantageous not to perform the power gating operation in the short power-down situation.

In association with the above description, a conventional memory device reduces power consumption by initiating the power gating operation at a point in time when an internally defined time (e.g., 2 μs) passes after the memory device enters the power-down state.

However, a time which is used as a criterion for distinguishing the long power-down and the short power-down may vary depending on a kind of a memory device (e.g., a capacity, a generation, or the degree of integration), a system in which the memory device is used, etc. Also, the power-down operation for minimizing power consumption of a system may vary for each system. Accordingly, like the conventional memory device described above, when the power-down operation is performed depending on an internally defined rule, there is a limitation in minimizing power consumption of the system in which the memory device is used or optimizing a system power.

As will be described later, according to one or more embodiments, the memory controller 1200 may variously control the power-down operation of the memory device 1100 by using the mode register 100 of the memory device 1100 and/or the first command. Accordingly, the minimization of power consumption of a system and high efficiency and optimization of a system power may be accomplished.

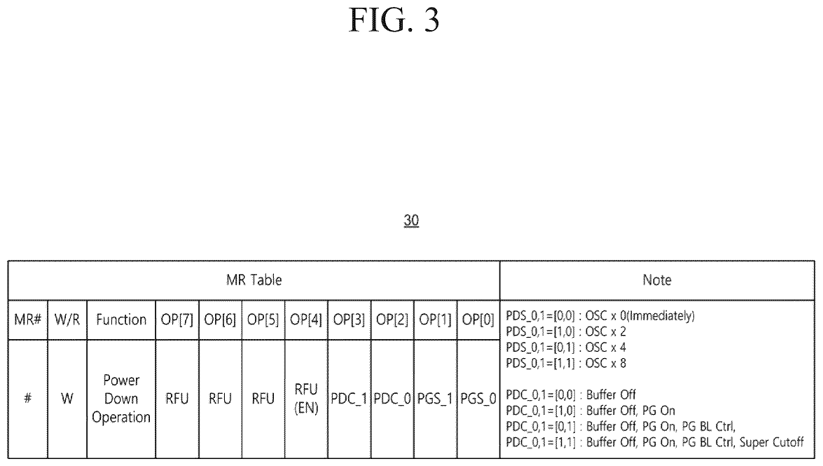

FIG. 3 is a table illustrating mode register information according to one or more embodiments of the present disclosure. A table 30 of FIG. 3 may be an example of information stored in the mode register 100 of FIG. 1, but the present disclosure is not limited thereto.

According to one or more embodiments of the present disclosure, the mode register 100 of the memory device 1100 may store the first setting value corresponding to the power-down operation to be performed in the power-down state and the second setting value corresponding to the start time of the power gating operation.

For example, the mode register 100 may include a power-down operation field storing the first setting value and the second setting value. Referring to FIG. 3, the mode register 100 may store a first setting value PDC_0,1 associated with the power-down operation by using operands OP[3:2] among eight operands OP[7:0] and a second setting value PDS_0,1 associated with the start time of the power gating operation by using operands OP[1:0]. Accordingly, in the example of FIG. 3, operands OP[3:0] may constitute the power-down operation field.

In this case, the first setting value PDC_0,1 may have one of a plurality of values [0,0], [1,0], [0,1], and [1,1], and the plurality of values [0,0], [1,0], [0,1], and [1,1] may respectively correspond to a plurality of power-down operations.

Referring to FIG. 3, [0,0] may correspond to a first power-down operation Buffer Off. The first power-down operation Buffer Off may refer to an operation of turning off the input/output buffer among the plurality of function blocks included in the peripheral circuit 1150.

[1,0] may correspond to a second power-down operation Buffer Off, PG On. The second power-down operation Buffer Off and PG On may include the first power-down operation Buffer Off and a power gating operation PG On for function blocks belonging to a first group from among the plurality of function blocks.

[0,1] may correspond to a third power-down operation Buffer Off and PG On, PG BL Ctrl. The third power-down operation Buffer Off and PG On, PG BL Ctrl may include the first power-down operation Buffer Off and a power gating operation PG On, PG BL Ctrl for function blocks belonging to a second group from among the plurality of function blocks. In this case, according to one or more embodiments, the second group may be a group further including a function block not belonging to the first group in addition to the function blocks of the first group.

[1,1] may correspond to a fourth power-down down operation Buffer Off and PG On, PG BL Ctrl, and Super Cutoff. The fourth power-down down operation Buffer Off and PG On, PG BL Ctrl, and Super Cutoff may include the first power-down operation Buffer Off and an operation PG On, PG BL Ctrl, and Super Cutoff of changing a level of a cut-off voltage (or a shut-off voltage) used in the power-down operation for the function blocks belonging to the second group from a first level to a second level.

The second setting value PDS_0,1 may have one of a plurality of values [0,0], [1,0], [0,1], and [1,1], and the plurality of values [0,0], [1,0], [0,1], and [1,1] may respectively correspond to a plurality of given times. The start time of the power gating operation corresponding to the second setting value may be a point in time when a given time corresponding to the second setting value passes after the memory device 1100 enters the power-down state. Accordingly, the start time of the power gating operation may be determined depending on the second setting value.

According to one or more embodiments, the plurality of given times may be an integer multiple of a reference time. In this case, the reference time may be, but is not limited to, a time corresponding to a period OSC of an output signal of an oscillator operating in the power-down state.

Referring to FIG. 3, [0,0] may correspond to a first given time OSC×0. The first given time OSC×0 may be a zero multiple of the oscillator period OSC. In this case, the start time of the power gating operation corresponding to the second setting value may be a time immediately after the memory device 1100 enters the power-down state.

[1,0] may correspond to a second given time OSC×2. The second given time OSC×2 may be two times the oscillator period OSC. In this case, the start time of the power gating operation corresponding to the second setting value may be a point in time when a time corresponding to two times the oscillator period OSC passes after the memory device 1100 enters the power-down state.

[0,1] may correspond to a third given time OSC×3. The third given time OSC×4 may be four times the oscillator period OSC. In this case, the start time of the power gating operation corresponding to the second setting value may be a point in time when a time corresponding to four times the oscillator period OSC passes after the memory device 1100 enters the power-down state.

[1,1] may correspond to a fourth given time OSC×8. The fourth given time OSC×8 may be eight times the oscillator period OSC. In this case, the start time of the power gating operation corresponding to the second setting value may be a point in time when a time corresponding to eight times the oscillator period OSC passes after the memory device 1100 enters the power-down state.

The plurality of given times are not limited to integer multiples of the reference time. According to one or more embodiments, the plurality of given times may be preset times such as 0 μs, 3 μs, 5 μs, and 10 μs. In this case, for example: [0,0] may correspond to 0 μs; [0,1] may correspond to 3 μs; [1,0] may correspond to 5 μs; and [1,1] may correspond to 10 μs. In this case, the start time of the power gating operation corresponding to [0,0] may be a time immediately after the memory device 1100 enters the power-down state. Also, the start time of the power gating operation corresponding to [0,1] may be a point in time when 3 μs passes after the memory device 1100 enters the power-down state. In addition, the start time of the power gating operation corresponding to [1,0] may be a point in time when 5 μs passes after the memory device 1100 enters the power-down state. Furthermore, the start time of the power gating operation corresponding to [1,1] may be a point in time when 10 μs passes after the memory device 1100 enters the power-down state.

According to one or more embodiments of the present disclosure, the mode register 100 may further include an enable field in which a setting value EN associated with whether the mode register 100 is enabled is stored. In the example of FIG. 3, an operand OP[4] may constitute the enable field. However, the present disclosure is not limited thereto.

In this case, the power-down control circuit 200 may control a power-down control operation of the memory device 1100 in different manners depending on the setting value EN of the enable field.

For example, when the mode register 100 is enabled, that is, when the setting value EN of the enable field is a first value (e.g., “1”), the power-down control circuit 200 may control the power-down operation by using the first setting value PDC_0,1 and the second setting value PDS_0,1 stored in the power-down operation field of the mode register 100.

When the mode register 100 is disabled, that is, when the setting value EN of the enable field is a second value (e.g., “0”), the power-down control circuit 200 may control the power-down operation based on the first command. In this case, the first command may include first command/address signals corresponding to the first setting value PDC_0,1 and second command/address signals corresponding to the second setting value PDS_0,1. An embodiment in which the power-down operation is performed based on the first command will be described in detail later.

In FIG. 3, an example in which the first setting value is implemented with two bits OP[3:2] and the second setting value is implemented with two bits OP[1:0] is described, but the disclosure is not limited thereto. For example, according to one or more embodiments, the first setting value and/or the second setting value may be implemented with a 1-bit operand OP or may be implemented with operands OPs of three or more bits.

In one or more embodiments, operands OP[5:3] may be used to store a first setting value PDC_0,1,2 associated with the power-down operation. In this case, the first setting value PDC_0,1,2 may have one of eight values such as [0,0,0], [0,0,1], . . . , [1,1,1]. Accordingly, the first setting value PDC_0,1,2 may have a value corresponding to one of eight power-down operations. Also, in one or more embodiments, operands OP[2:0] may be used to store a second setting value PDS_0,1,2 associated with the start time associated with the power-gating operation. In this case, the second setting value PDS_0,1,2 may have one of eight values such as [0,0,0], [0,0,1], . . . , [1,1,1]. Accordingly, the second setting value PDS_0,1,2 may have a value corresponding to one of eight start times of the power-down operation.

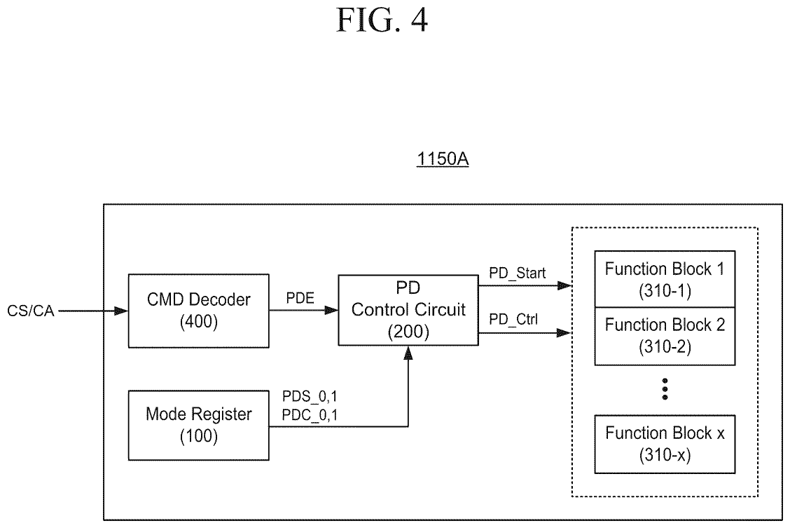

FIG. 4 is a block diagram for describing an operation of a memory device according to one or more embodiments of the present disclosure. A peripheral circuit 1150A of FIG. 4 may be, but is not limited to, an example of the peripheral circuit 1150 of FIG. 1.

Referring to FIG. 4, the peripheral circuit 1150A may include a command decoder 400, the mode register 100, a power-down control circuit 200, and a plurality of function blocks 310-1 to 310-x.

The command decoder 400 may decode a chip select signal CS and a command/address signal CA to generate control signals corresponding to a command. For example, the memory controller 1200 may generate the first command by combining the chip select signal CS and the command/address signal CA and may provide the memory device 1100 with the first command thus generated. In this case, the first command which is a command for allowing the memory device 1100 to enter the power-down state may be, but is not limited to, a power down entry (PDE) command. Accordingly, the command decoder 400 may generate a power down entry (PDE) signal by decoding the first command thus received and may provide the generated PDE signal to the power-down control circuit 200.

The mode register 100 may store the first setting value PDC_0,1 corresponding to the power-down operation to be performed in the power-down state and the second setting value PDS_0,1 corresponding to the start time of the power gating operation. For example, the first setting value PDC_0,1 and the second setting value PDS_0,1 may be stored in the mode register 100 based on the third command received from the memory controller 1200.

The plurality of function blocks 310-1 to 310-x may be function blocks targeted for the power-down operation from among the plurality of function blocks included in the peripheral circuit 1150A. In this case, the power-down operation may include a turn-off operation and/or the power gating operation. In one or more embodiments, the turn-off operation may refer to an operation of blocking an operation power of the corresponding function block such that the operation of the corresponding function block is stopped. The power gating operation may refer to an operation of completely blocking the external power being provided to the corresponding function block.

According to one or more embodiments, the first function block 310-1 may be targeted for the turn-off operation. For example, the first function block 310-1 may be, but is not limited to, the input/output buffer. The input/output buffer may be connected to the memory controller 1200 through a pad and may exchange data with the memory controller 1200.

Also, according to one or more embodiments, the second function block 310-2 to the fifth function block 310-5 may be targeted for the power gating operation. For example, the second function block 310-2 may be the column decoder. The column decoder may select a column of the memory cell array 1130 based on a column address. Also, the third function block 310-3 may be the bank control circuit. The bank control circuit may select a bank of the memory cell array 1130 based on a bank address. In addition, the fourth function block 310-4 may be the error correction code (ECC) engine. The ECC engine may perform the ECC encoding operation or the ECC decoding operation. Also, the fifth function block 310-5 may be the row decoder. The row decoder may select a row of the memory cell array 1130 based on a row address.

However, this is provided only as an example, and the plurality of function blocks 310-1 to 310-x are not limited thereto.

The power-down control circuit 200 may control the power-down operation of the memory device 1100. For example, the power-down control circuit 200 may generate a control signal PD_ctrl for controlling the power-down operation and a start signal PD_start triggering the power gating operation, based on the PDE signal provided from the command decoder 400 and the first and second setting values stored in the mode register 100.

The power-down control circuit 200 may control the power-down operation of the memory device 1100 by controlling operations of the plurality of function blocks 310-1 to 310-x through the control signal PD_ctrl and the start signal PD_start.

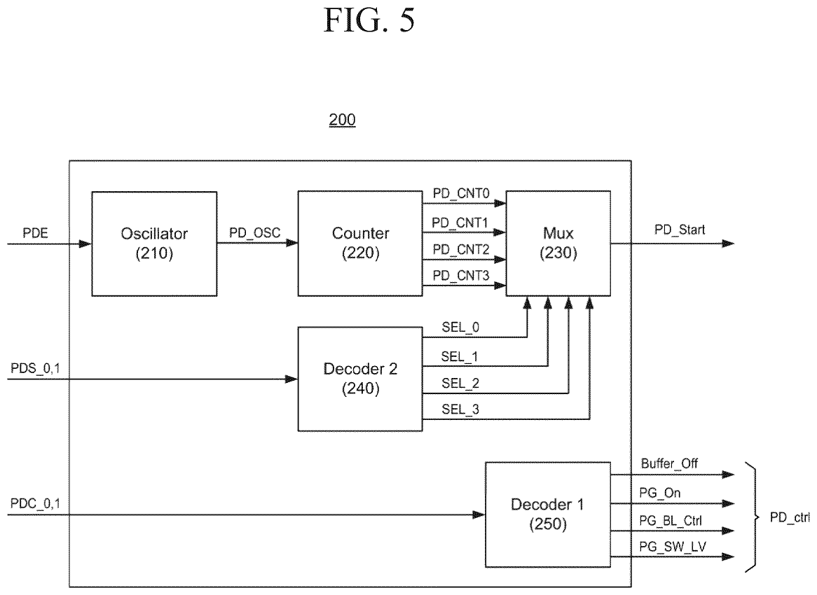

Below, a configuration and an operation of the power-down control circuit 200 will be described in detail with reference to FIGS. 5 to 7.

FIG. 5 is a block diagram of a power-down control circuit according to one or more embodiments of the present disclosure. The power-down control circuit 200 of FIG. 5 may be, but is not limited to, an implementation example of the power-down control circuit 200 of FIGS. 1 and 4.

Referring to FIG. 5, the power-down control circuit 200 may include an oscillator 210, a counter 220, a multiplexer 230, a first decoder 250, and a second decoder 240.

The oscillator 210 may output a clock signal PD_OSC based on the first command. For example, when the PDE signal is received from the command decoder 400 based on the first command, the oscillator 210 may output the clock signal PD_OSC with a given period to the counter 220. In this case, the oscillator 210 may be an oscillator operating even in the power-down state; according to one or more embodiments, the oscillator 210 may be, but is not limited to, an oscillator for the self-refresh operation.

The counter 220 may output a plurality of period signals PD_CNT0, PD_CNT1, PD_CNT2, and PD_CNT3 associated with the start time of the power gating operation based on the clock signal PD_OSC which the oscillator 210 outputs.

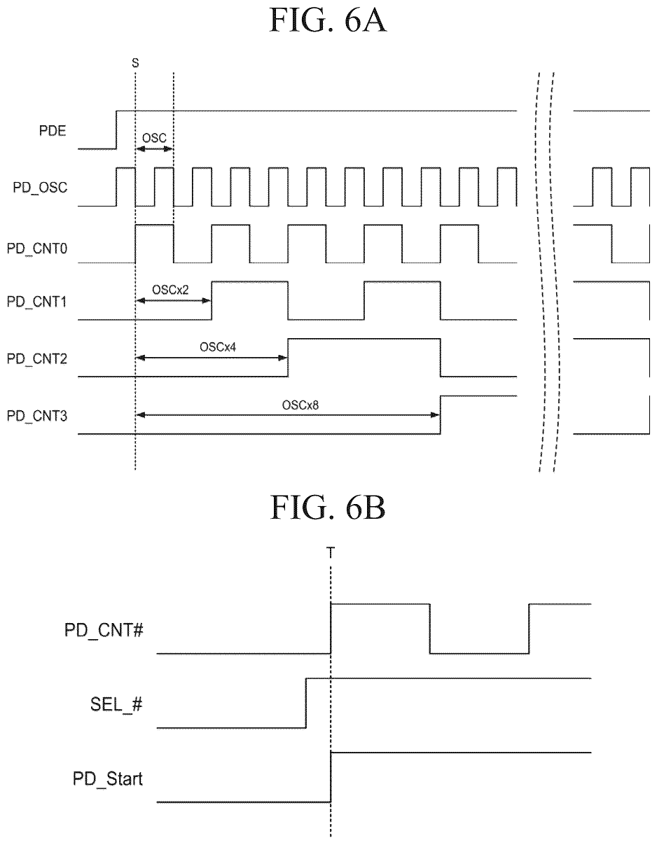

FIG. 6A is an operation timing diagram of the counter 220 according to one or more embodiments of the present disclosure.

According to one or more embodiments, the period of each of the plurality of period signals PD_CNT0, PD_CNT1, PD_CNT2, and PD_CNT3 may be an integer multiple of the period OSC of the clock signal PD_OSC which the oscillator 210 outputs.

Referring to FIG. 6A, the period of the first period signal PD_CNT0 may be two times the period OSC of the clock signal PD_OSC. Also, the second period signal PD_CNT1 may be four times the period OSC of the clock signal PD_OSC, the third period signal PD_CNT2 may be eight times the period OSC of the clock signal PD_OSC, and the fourth period signal PD_CNT3 may be sixteen times the period OSC of the clock signal PD_OSC.

According to one or more embodiments, the start time of each of the plurality of period signals PD_CNT0, PD_CNT1, PD_CNT2, and PD_CNT3 may be a point in time when a given time passes from a time point “S” at which the counter 220 is capable of outputting a period signal. In this case, the given time may differ for each of the plurality of period signals PD_CNT0, PD_CNT1, PD_CNT2, and PD_CNT3.

Referring to FIG. 6A, the start time of the first period signal PD_CNT0 may be a point in time when a time interval corresponding to zero times the period OSC of the clock signal PD_OSC passes from the time point “S”, where the point “S” is the point at which the counter 220 is capable of outputting a period signal. Because zero times the period OSC of the clock signal PD_OSC is “0”, the start time of the first period signal PD_CNT0 may be the time point “S” at which the counter 220 is capable of outputting a period signal. Also, the start time of the second period signal PD_CNT1 may be a point in time when a time corresponding to two times the period OSC of the clock signal PD_OSC passes from the time point “S” at which the counter 220 is capable of outputting a period signal. In addition, the start time of the third period signal PD_CNT2 may be a point in time when a time corresponding to four times the period OSC of the clock signal PD_OSC passes from the time point “S” at which the counter 220 is capable of outputting a period signal. Furthermore, the start time of the first period signal PD_CNT3 may be a point in time when a time corresponding to eight times the period OSC of the clock signal PD_OSC passes from the time point “S” at which the counter 220 is capable of outputting a period signal.

Returning to FIG. 5, the second decoder 240 may decode the second setting value PDS_0,1 to output selection signals SEL_0, SEL_1, SEL_2, and SEL_3 for selecting the start time of the power gating operation. For example, when the second setting value PDS_0,1 is [0,0], the second decoder 240 may activate only the first selection signal SEL_0 among the selection signals SEL_0, SEL_1, SEL_2, and SEL_3. Also, when the second setting value PDS_0,1 is [1,0], the second decoder 240 may activate only the second selection signal SEL_1 among the selection signals SEL_0, SEL_1, SEL_2, and SEL_3. In addition, when the second setting value PDS_0,1 is [0,1], the second decoder 240 may activate only the third selection signal SEL_2 among the selection signals SEL_0, SEL_1, SEL_2, and SEL_3. Furthermore, when the second setting value PDS_0,1 is [1,1], the second decoder 240 may activate only the fourth selection signal SEL_3 among the selection signals SEL_0, SEL_1, SEL_2, and SEL_3.

The multiplexer 230 may output the start signal PD_start triggering the power gating operation, based on the selection signals SEL_0, SEL_1, SEL_2, and SEL_3 and the plurality of period signals PD_CNT0, PD_CNT1, PD_CNT2, and PD_CNT3.

FIG. 6B is an operation timing diagram of the multiplexer 230 according to one or more embodiments of the present disclosure. Referring to FIG. 6B, the multiplexer 230 may output the start signal PD_start having a start time corresponding to a start time “T” of a period signal PD_CNT #, which is selected based on a selection signal SEL_#, from among the plurality of period signals PD_CNT0, PD_CNT1, PD_CNT2, and PD_CNT3.

For example, when the first selection signal SEL_0 is activated, the multiplexer 230 may output the start signal PD_start having a start time corresponding to the start time of the first period signal PD_CNT0. Also, when the second selection signal SEL_1 is activated, the multiplexer 230 may output the start signal PD_start having a start time corresponding to the start time of the second period signal PD_CNT1. In addition, when the third selection signal SEL_2 is activated, the multiplexer 230 may output the start signal PD_start having a start time corresponding to the start time of the third period signal PD_CNT2. Furthermore, when the fourth selection signal SEL_3 is activated, the multiplexer 230 may output the start signal PD_start having a start time corresponding to the start time of the fourth period signal PD_CNT3.

Returning to FIG. 5, the first decoder 250 may decode the first setting value PDC_0,1 to output control signals for controlling the power-down operation. In this case, according to one or more embodiments, the control signals for controlling the power-down operation may include a first control signal Buffer_Off for turning off the input/output buffer, a second control signal PG_On for the power gating operation for the function blocks belonging to the first group from among the plurality of function blocks, a third control signal PG_BL_Ctrl for the power gating operation for the function blocks belonging to the second group from among the plurality of function blocks, and a fourth control signal PG_SW_LV for controlling a level of a cut-off voltage to be used in the power gating operation.

According to one or more embodiments, the first control signal Buffer_Off may be applied to a switch which turns on or turns off the input/output buffer. Accordingly, the operation of the input/output buffer may be controlled depending on whether the first control signal Buffer_Off is activated.

Also, the second control signal PG_On may be applied to a power gating switch which blocks or provides the external power to the function blocks belonging to the first group from among the plurality of function blocks. Accordingly, the external power may be blocked or provided to the function blocks belonging to the first group, depending on whether the second control signal PG_On is activated.

In addition, the third control signal PG_BL_Ctrl may be applied to a power gating switch which blocks or provides the external power to the function blocks not belonging to the first group or a power gating switch which blocks or provides the external power to some of the function blocks belonging to the first group. Accordingly, the external power may be blocked or provided to the function block not belonging to the first group, depending on whether the third control signal PG_BL_Ctrl is activated. Furthermore, the external power may be blocked or provided to some of the function blocks belonging to the first group, depending on whether the third control signal PG_BL_Ctrl is activated.

Also, the fourth control signal PG_SW_LV may change the level of the cut-off voltage to be used in the power gating operation. For example, voltage levels of the second control signal PG_On and the third control signal PG_BL_Ctrl which are activated may be a first level. Accordingly, when the fourth control signal PG_SW_LV is deactivated, the power gating operation may be performed based on the cut-off voltage of the first level. However, when the fourth control signal PG_SW_LV is activated, the power gating operation may be performed based on the cut-off voltage of a second level different from the first level.

The control signal PD_ctrl described with reference to FIG. 4 may include the first to fourth control signals Buffer_Off, PG_On, PG_BL_Ctrl, and PG_SW_LV which the first decoder 250 outputs. Accordingly, the power-down control circuit 200 may control the power-down operation of the memory device 1100 by controlling operations of the plurality of function blocks 310-1 to 310-x through the first to fourth control signals Buffer_Off, PG_On, PG_BL_Ctrl, and PG_SW_LV and the start signal PD_start.

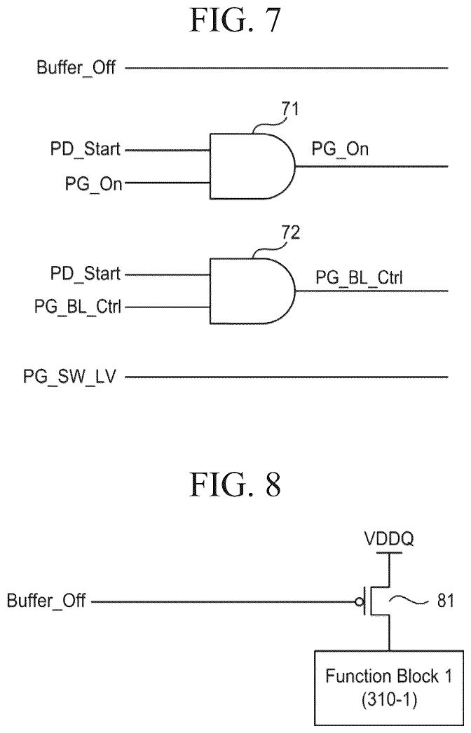

FIG. 7 is a diagram illustrating an example in which a start time of a power gating operation is applied to a control signal for a power gating operation.

As described above, because the second control signal PG_On and the third control signal PG_BL_Ctrl are associated with the power gating operation, the start time of the power gating operation according to the second setting value should be applied to the second control signal PG_On and the third control signal PG_BL_Ctrl.

According to one or more embodiments, the start signal PD_start and an AND gate may be used to apply the start time of the power gating operation according to the second setting value to the second control signal PG_On and the third control signal PG_BL_Ctrl. However, the present disclosure is not limited thereto. For example, any other methods may be used depending on embodiments.

Referring to FIG. 7, the second control signal PG_On and the start signal PD_start may be input to an AND gate 71. Because the AND gate 71 outputs “1” only when all of two input signals are “1”, the AND gate 71 may output the second control signal PG_On to which the start time of the power gating operation according to the second setting value is applied. Also, the third control signal PG_BL_Ctrl and the start signal PD_start may be input to an AND gate 72. Accordingly, the AND gate 72 may output the third control signal PG_BL_Ctrl to which the start time of the power gating operation according to the second setting value is applied.

Because the first control signal Buffer_Off is not associated with the power gating operation and the fourth control signal PG_SW_LV only controls the level of the cut-off voltage, there is no need to apply the start time of the power gating operation according to the second setting value to the first control signal Buffer_Off and the fourth control signal PG_SW_LV.

Below, the power-down operation according to one or more embodiments of the present disclosure will be described with reference to FIGS. 8 through 11. Below, first to fourth power-down operations described with reference to FIG. 3 will be described as an example. However, the disclosure is not limited thereto.

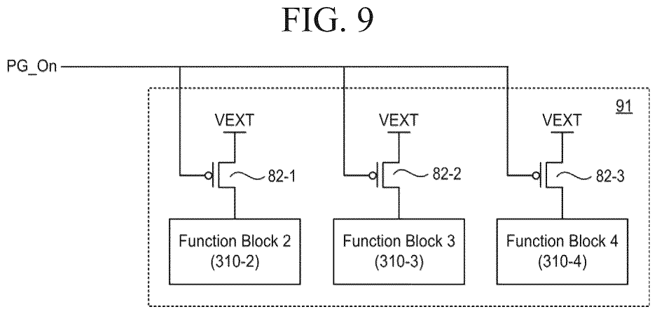

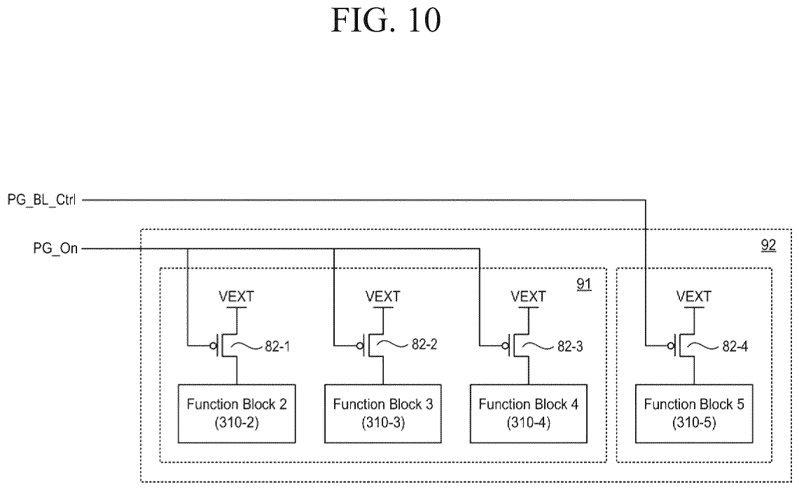

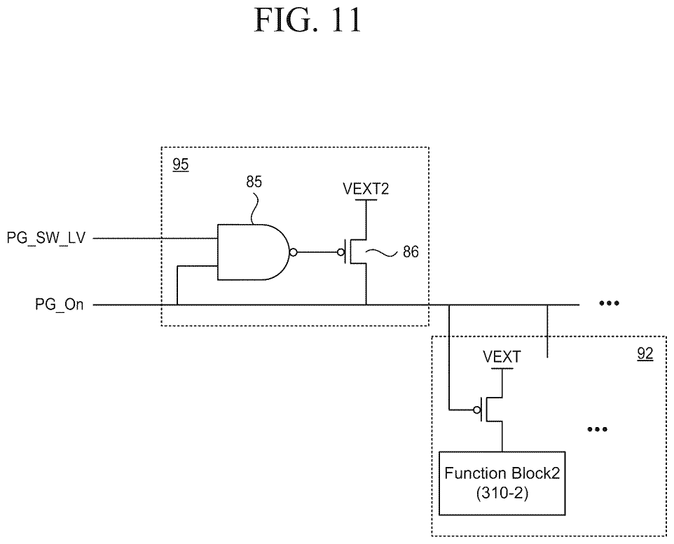

FIG. 8 is a diagram for describing a first power-down operation according to one or more embodiments of the present disclosure. FIG. 9 is a diagram for describing a second power-down operation according to one or more embodiments of the present disclosure. FIG. 10 is a diagram for describing a third power-down operation according to one or more embodiments of the present disclosure. FIG. 11 is a diagram for describing a fourth power-down operation according to one or more embodiments of the present disclosure.

According to one or more embodiments of the present disclosure, the first to fourth power-down operations may be implemented and performed through a combination of the first to fourth control signals Buffer_Off, PG_On, PG_BL_Ctrl, and PG_SW_LV and the start signal PD_start.

Table 1 below shows an example of combinations of the first to fourth control signals Buffer_Off, PG_On, PG_BL_Ctrl, and PG_SW_LV, which make the first to fourth power-down operations described with reference to FIG. 3 executable. In Table 1, “1” indicates the activation of the corresponding control signal, and “0” indicates the deactivation of the corresponding control signal. Below, the description will be given under the assumption that the start time of the power gating operation is applied to the second control signal PG_On and the third control signal PG_BL_Ctrl.

TABLE 1

| | First PD | Second PD | Third PD | Fourth PD |
|---|---|---|---|---|
| | operation | operation | operation | operation |
| Buffer Off | 1 | 1 | 1 | 1 |
| PG_On | 0 | 1 | 1 | 1 |
| PG_BL_Ctrl | 0 | 0 | 1 | 1 |
| PG_SW_LV | 0 | 0 | 0 | 1 |

Referring to Table 1 and FIGS. 3 and 5, the first setting value PDC_0,1 corresponding to the first power-down operation may be [0,0], and the first power-down operation may refer to an operation of turning off the input/output buffer.

When the first setting value PDC_0,1 is [0,0], the first decoder 250 of the power-down control circuit 200 may activate and output the first control signal Buffer_Off to turn off the input/output buffer. In this case, the remaining control signals PG_On, PG_BL_Ctrl, and PG_SW_LV may remain in a deactivated state.

Because the first power-down operation does not include the power gating operation, when the first setting value PDC_0,1 is [0,0], the second setting value indicating the start time of the power gating operation may be ignored.

Referring to FIG. 8, the first function block 310-1 may be the input/output buffer. The first function block 310-1 may be turned on or turned off depending on the on/off operation of a switch 81. The first control signal Buffer_Off may control the on/off operation of the switch 81. In one or more embodiments, the switch 81 may be implemented with a PMOS transistor, but the present disclosure is not limited thereto.

For example, when the first control signal Buffer_Off is deactivated, the switch 81 may be turned on. In this case, an operation voltage VDDQ may be applied to the first function block 310-1, and thus, the first function block 310-1 may be turned on. Also, when the first control signal Buffer_Off is activated, the switch 81 may be turned off. In this case, the operation voltage VDDQ may be blocked, and thus, the first function block 310-1 may be turned off. Herein, the operation voltage VDDQ is not the external power which is blocked in the power gating operation.

The first setting value PDC_0,1 corresponding to the second power-down operation may be [1,0], and the second power-down operation may include the first power-down operation, and the power gating operation for the function blocks belonging to the first group from among the plurality of function blocks.

When the first setting value PDC_0,1 is [1,0], the first decoder 250 of the power-down control circuit 200 may activate and output the first control signal Buffer_Off and the second control signal PG_On. In this case, the third control signal PG_BL_Ctrl and the fourth control signal PG_SW_LV may maintain a deactivated state.

Accordingly, the input/output buffer may be turned off, and the external power being provided to the function blocks belonging to the first group may be blocked at the start time corresponding to the second setting value.

Referring to FIG. 9, a first group 91 may include the second function block 310-2, the third function block 310-3, and the fourth function block 310-4. For example, the second function block 310-2 may be the column decoder, the third function block 310-3 may be the bank control circuit, and the fourth function block 310-4 may be the ECC engine. However, the present disclosure is not limited thereto.

Depending on the on/off operation of a corresponding one of switches 82-1, 82-2, and 82-3, an external power VEXT may be blocked or provided to each of the function blocks 310-2, 310-3, and 310-4 belonging to the first group 91. The second control signal PG_On may control the on/off operations of the switches 82-1, 82-2, and 82-3. In one or more embodiments, the switches 82-1, 82-2, and 82-3 may be implemented with a PMOS transistor, but the present disclosure is not limited thereto.

For example, when the second control signal PG_On is deactivated, the switches 82-1, 82-2, and 82-3 may be turned on. In this case, the external power VEXT may be provided to the function blocks 310-2, 310-3, and 310-4 belonging to the first group 91, and the function blocks 310-2, 310-3, and 310-4 belonging to the first group 91 may normally operate.

When the second control signal PG_On is activated, the switches 82-1, 82-2, and 82-3 may be turned off. In this case, the external power VEXT being provided to the function blocks 310-2, 310-3, and 310-4 belonging to the first group 91 may be blocked. That is, there may be performed the power gating operation for the function blocks 310-2, 310-3, and 310-4 belonging to the first group 91, based on the second control signal PG_On thus activated.

As described above, the second power-down operation may include the first power-down operation, and the power gating operation for the function blocks belonging to the first group. Accordingly, when the first setting value PDC_0,1 is [1,0], an operation of turning off the first function block 310-1 of FIG. 8 is together performed in addition to the power gating operation for the function blocks 310-2, 310-3, and 310-4 belonging to the first group 91.

The first setting value PDC_0,1 corresponding to the third power-down operation may be [0,1], and the third power-down operation may include the first power-down operation, and the power gating operation for the function blocks belonging to the second group from among the plurality of function blocks.

When the first setting value PDC_0,1 is [0,1], the first decoder 250 of the power-down control circuit 200 may activate and output the first control signal Buffer_Off, the second control signal PG_On, and the third control signal PG_BL_Ctrl. In this case, the fourth control signal PG_SW_LV may maintain a deactivated state.

Accordingly, the input/output buffer may be turned off, and the external power being provided to the function blocks belonging to the second group may be blocked at the start time corresponding to the second setting value.

According to one or more embodiments, the second group may be a group further including a function block not belonging to the first group in addition to the function blocks of the first group. Referring to FIG. 10, a second group 92 may be a group which further includes the fifth function block 310-5 not belonging to the first group 91 of FIG. 1 in addition to the function blocks of the first group 91. That is, the second group 92 may include the function blocks 310-2, 310-3, and 310-4 belonging to the first group 91 and the added function block, that is, the fifth function block 310-5. In this case, the fifth function block 310-5 may be, for example, the row decoder, but the present disclosure is not limited thereto.

Depending on the on/off operation of a corresponding one of the switches 82-1, 82-2, and 82-3, the external power VEXT may be blocked or provided to each of the function blocks 310-2, 310-3, and 310-4 belonging to the first group 91. Also, depending on the on/off operation of a switch 82-4, the external power VEXT may be blocked or provided to the added function block, that is, the fifth function block 310-5. The second control signal PG_On may control the on/off operations of the switches 82-1, 82-2, and 82-3. Also, the third control signal PG_BL_Ctrl may control the on/off operation of the switch 82-4. In one or more embodiments, the switches 82-1, 82-2, 82-3, and 82-4 may be implemented with a PMOS transistor, but the present disclosure is not limited thereto.

How the function blocks 310-2, 310-3, and 310-4 belonging to the first group 91 operate depending on whether the second control signal PG_On is activated is described in detail with reference to FIG. 9, and thus, additional description will be omitted to avoid redundancy. When the third control signal PG_BL_Ctrl is deactivated, the switch 82-4 may be turned on. In this case, the external voltage VEXT may be provided to the fifth function block 310-5, and thus, the fifth function block 310-5 may operate normally. When the third control signal PG_BL_Ctrl is activated, the switch 82-4 may be turned off. In this case, the external power VEXT being provided to the fifth function block 310-5 may be blocked.

As described above, the third power-down operation may include the first power-down operation, and the power gating operation for the function blocks belonging to the second group. In this case, the second group 92 may include the function blocks 310-2, 310-3, and 310-4 belonging to the first group 91 and the added function block, that is, the fifth function block 310-5. Accordingly, both the second control signal PG_On and the third control signal PG_BL_Ctrl should be activated to perform the power gating operation for the function blocks 310-2, 310-3, 310-4, and 310-5 belonging to the second group. Also, the first control signal Buffer_Off should be activated for the first power-down operation.

The first setting value PDC_0,1 corresponding to the fourth power-down operation is [1,1], and the fourth power-down operation may include the first power-down operation, and an operation of changing the level of the cut-off voltage, which is used in the power gating operation for the function blocks belonging to the second group, from the first level to the second level.

When the first setting value PDC_0,1 is [1,1], the first decoder 250 of the power-down control circuit 200 may activate and output the first control signal Buffer_Off, the second control signal PG_On, the third control signal PG_BL_Ctrl, and the fourth control signal PG_SW_LV.

Accordingly, the input/output buffer may be turned off, and the external power being provided to the function blocks belonging to the second group may be blocked at the start time corresponding to the second setting value, based on the cut-off voltage of the second level.

According to one or more embodiments, in the third power-down operation, the power gating operation for the function blocks 310-2, 310-3, 310-4, and 310-5 belonging to the second group may be performed based on the cut-off voltage of the first level. For example, voltage levels of the second control signal PG_On and the third control signal PG_BL_Ctrl which are activated may be the first level. In the power gating operation, because the activated second and third control signals PG_On and PG_BL_Ctrl are applied to the switches 82-1, 82-2, 82-3, and 82-4, the voltage levels of the activated second and third control signals PG_On and PG_BL_Ctrl may correspond to the cut-off voltage level of the switches 82-1, 82-2, 82-3, and 82-4. In this case, for example, the first level may be identical to the voltage level of the external power VEXT, but the present disclosure is not limited thereto. In this case, even though the switches 82-1, 82-2, 82-3, and 82-4 are cut off based on the cut-off voltage (e.g., VEXT) of the first level, a minute leakage current may flow through the switches 82-1, 82-2, 82-3, and 82-4.

When the fourth control signal PG_SW_LV is activated, the power gating operation for the function blocks 310-2, 310-3, 310-4, and 310-5 belonging to the second group may be performed based on the cut-off voltage of the second level. That is, the switches 82-1, 82-2, 82-3, and 82-4 may be cut off based on a cut-off voltage VEXT2 of the second level. In this case, according to one or more embodiments, the second level may be higher in value than the first level. It is assumed that the switches 82-1, 82-2, 82-3, and 82-4 are implemented with a PMOS transistor. In this case, when the cut-off voltage (e.g., VEXT2) of a relatively high level is applied thereto, the switches 82-1, 82-2, 82-3, and 82-4 may be cut off more strongly, and thus, the leakage current flowing through the switches 82-1, 82-2, 82-3, and 82-4 may be relatively decreased.

Referring to FIG. 11, the second control signal PG_On and the fourth control signal PG_SW_LV may be input to a cut-off voltage change circuit 95. The cut-off voltage change circuit 95 may include a NAND gate 85 and a switch 86. Two inputs of the NAND gate 85 may be the second control signal PG_On and the fourth control signal PG_SW_LV. The switch 86 may include a gate terminal to which an output of the NAND gate 85 is applied, a source terminal connected to the cut-off voltage VEXT2 of the second level, and a drain terminal connected to gate terminals of the switches 82-1, 82-2, and 82-3.

When the fourth control signal PG_SW_LV is deactivated, the NAND gate 85 outputs a high value, and the switch 86 maintains an off state. In this case, the switches 82-1, 82-2, and 82-3 may be turned on/off depending on whether the second control signal PG_On is activated. For example, when the second control signal PG_On thus activated is applied to the switches 82-1, 82-2, and 82-3, the external power VEXT being provided to the function blocks 310-2, 310-3, and 310-4 may be blocked based on the cut-off voltage (VEXT) of the first level.

When both the second control signal PG_On and the fourth control signal PG_SW_LV are activated, the NAND gate 85 outputs a low value, and the switch 86 is turned on. Accordingly, the cut-off voltage VEXT2 of the second level may be applied to the gate terminals of the switches 82-1, 82-2, and 82-3. In this case, the external power VEXT being provided to the function blocks 310-2, 310-3, and 310-4 may be blocked based on the cut-off voltage VEXT2 of the second level.

For convenience of illustration, some of the function blocks belonging to the second group 92 are illustrated in FIG. 11. However, as illustrated in FIG. 10, the fifth function block 310-5 whose on/off is controlled by the third control signal PG_BL_Ctrl may be included in the second group 92. That is, as in the cut-off voltage change circuit 95, there may be provided a cut-off voltage change circuit to which the third control signal PG_BL_Ctrl and the fourth control signal PG_SW_LV are applied. Accordingly, when both the third control signal PG_BL_Ctrl and the fourth control signal PG_SW_LV are activated, the cut-off voltage VEXT2 of the second level may be applied to the gate terminal of the switch 82-4. In this case, the external power VEXT being provided to the fifth function block 310-5 may be blocked based on the cut-off voltage VEXT2 of the second level.

According to the above description, when all of the first control signal Buffer_Off, the second control signal PG_On, the third control signal PG_BL_Ctrl, and the fourth control signal PG_SW_LV are activated, the fourth power-down operation may be performed.

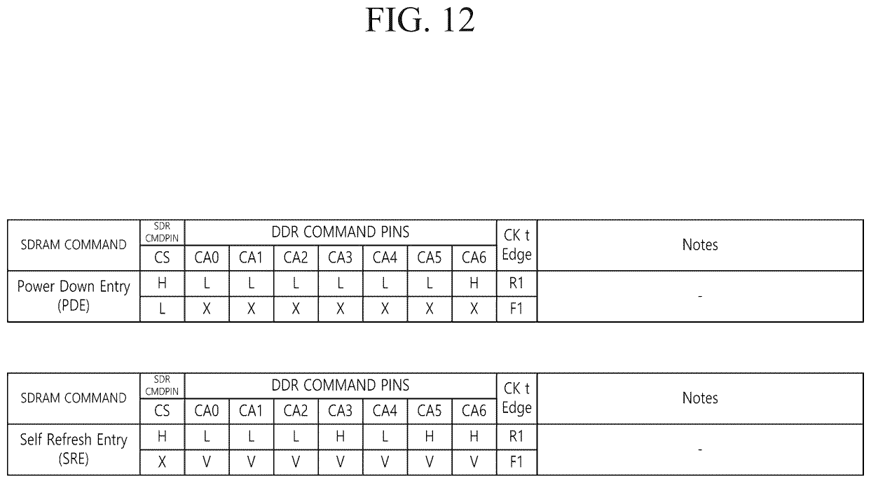

FIG. 12 is a diagram illustrating examples of a first command according to one or more embodiments of the present disclosure. Referring to FIG. 12, the first command may be a power down entry (PDE) command. Alternatively, the first command may be a self-refresh entry (SRE) command. The memory device 1100 may operate after entering the power-down state (or a power-down mode) based on the PDE command or the SRE command received from the memory controller 1200.

When the memory device 1100 enters the power-down state, the memory device 1100 may perform the power-down operation based on the first setting value and the second setting value stored in the mode register 100. In detail, the memory device 1100 may perform the power-down operation corresponding to the first setting value in the power-down state. In this case, the memory device 1100 may perform the power gating operation at the start time corresponding to the second setting value.

The memory device 1100 may exit from the power-down state based on the second command. In this case, the second command may be, but is not limited to, a power down exit (PDX) command. For example, when the PDX command is received from the memory controller 1200 while performing the power-down operation in the power-down state, the memory device 1100 may exit from the power-down state and may stop the power-down operation.

In one or more embodiments, the PDX command may be received before the start time corresponding to the second setting value arrives after entering the power-down state. In this case, the memory device 1100 may not perform the power gating operation even though the start time corresponding to the second setting value arrives.

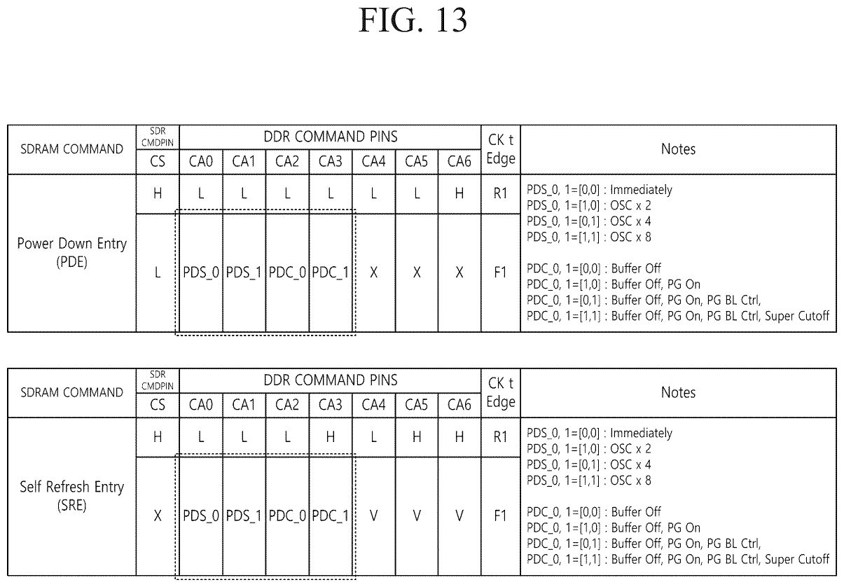

FIG. 13 is a diagram illustrating examples of a first command according to one or more embodiments of the present disclosure.

According to one or more embodiments, the memory controller 1200 may control the power-down operation of the memory device 1100 by using the first command. For example, the memory controller 1200 may transmit information associated with the power-down operation to the memory device 1100 by using some of command/address signals constituting the first command. In this case, the information associated with the power-down operation may include the first setting value corresponding to the power-down operation to be perform in the power-down state and the second setting value corresponding to the start time of the power gating operation.

Comparing the PDE command of FIG. 13 with the PDE command of FIG. 12, it may be understood that the first setting value PDC_0,1 and the second setting value PDS_0,1 are included in some command/address signals of the PDE command of FIG. 13. In this case, the first setting value PDC_0,1 and the second setting value PDS_0,1 included in the PDE command of FIG. 13 may respectively correspond to the first setting value PDC_0,1 and the second setting value PDS_0,1 described with reference to FIG. 3. The above description may also be applied to the SRE command of FIG. 13.

When the first command implemented like the examples of FIG. 13 is received, the memory device 1100 may perform the power-down operation based on the first command thus received.

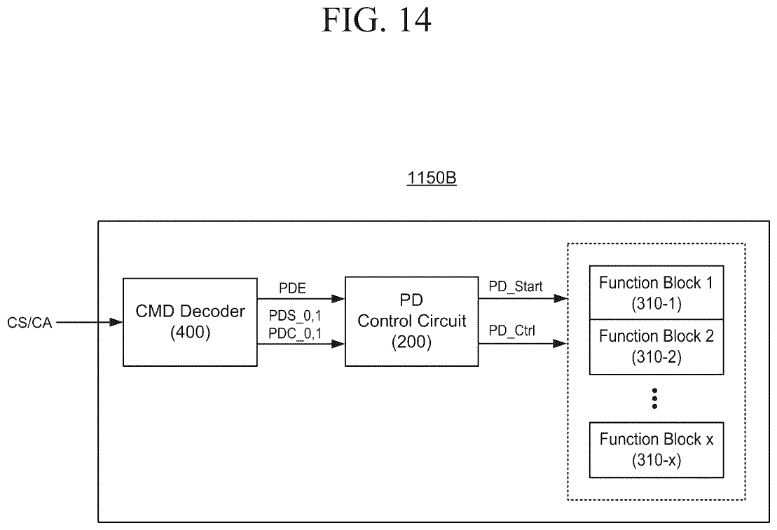

FIG. 14 is a block diagram for describing an operation of a memory device according to one or more embodiments of the present disclosure. A peripheral circuit 1150B of FIG. 14 may be, but is not limited to, an example of the peripheral circuit 1150 of FIG. 1.

Referring to FIG. 14, the peripheral circuit 1150B may include the command decoder 400, the power-down control circuit 200, and the plurality of function blocks 310-1 to 310-x. In describing FIG. 14, the description which is given above will be omitted or simplified.

The command decoder 400 may decode the chip select signal CS and the command/address signal CA to generate control signals corresponding to a command. For example, the memory controller 1200 may generate the first command, which is described with reference to FIG. 13, by combining the chip select signal CS and the command/address signal CA and may provide the memory device 1100 with the first command thus generated. Accordingly, the command decoder 400 may decode the first command to generate the PDE signal, the first setting value PDC_0,1, and the second setting value PDS_0,1 and may provide the generated PDE signal, the first setting value PDC_0,1, and the second setting value PDS_0,1 to the power-down control circuit 200.

The power-down control circuit 200 may control the power-down operation of the memory device 1100. For example, the power-down control circuit 200 may generate the control signal PD_ctrl for controlling the power-down operation and the start signal PD_start triggering the power gating operation, based on the PDE signal, the first setting value PDC_0,1, and the second setting value PDS_0,1 provided from the command decoder 400. The power-down control circuit 200 may control the power-down operation of the memory device 1100 by controlling operations of the plurality of function blocks 310-1 to 310-x through the control signal PD_ctrl and the start signal PD_start.

The manner in which the power-down control circuit 200 generates the control signal PD_ctrl and the start signal PD_start and controls operations of the plurality of function blocks 310-1 to 310-x through the generated signals is described in detail with reference to FIGS. 5 through 11, and thus, additional description will be omitted to avoid redundancy.

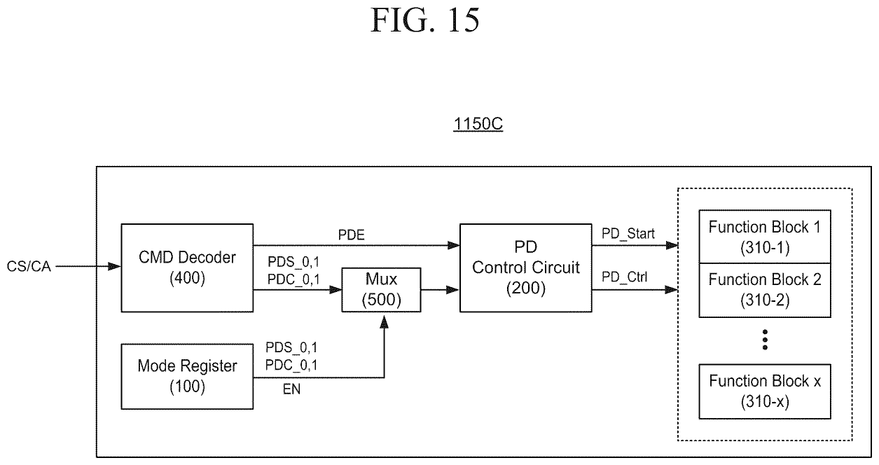

FIG. 15 is a block diagram for describing an operation of a memory device according to one or more embodiments of the present disclosure. A peripheral circuit 1150C of FIG. 15 may be, but is not limited to, an example of the peripheral circuit 1150 of FIG. 1.

Referring to FIG. 15, the peripheral circuit 1150C may include the command decoder 400, the mode register 100, the power-down control circuit 200, a multiplexer 500, and the plurality of function blocks 310-1 to 310-x. In describing FIG. 15, the description which is given above will be omitted or simplified.

The command decoder 400 may decode the chip select signal CS and the command/address signal CA to generate control signals corresponding to a command. For example, the memory controller 1200 may generate the first command, which is described with reference to FIG. 13, by combining the chip select signal CS and the command/address signal CA and may provide the memory device 1100 with the first command thus generated. Accordingly, the command decoder 400 may decode the first command to generate the PDE signal, the first setting value PDC_0,1, and the second setting value PDS_0,1. In this case, the PDE signal may be provided to the power-down control circuit 200. Also, the first setting value PDC_0,1 and the second setting value PDS_0,1 may be provided to a multiplexer 500.

The mode register 100 may store the first setting value PDC_0,1 and the second setting value PDS_0,1 in the power-down operation field. Also, the mode register 100 may store the setting value EN associated with whether the mode register 100 is enabled in the enable field. In this case, the setting value EN associated with whether the mode register 100 is enabled, the first setting value PDC_0,1 and the second setting value PDS_0,1 may be stored in the mode register 100 based on the MRW or MRS command received from the memory controller 1200. The setting value EN associated with whether the mode register 100 is enabled, the first setting value PDC_0,1 and the second setting value PDS_0,1, which are all stored in the mode register 100, may be provided to the multiplexer 500.

The multiplexer 500 may select either the first and second setting values PDC_0,1 and PDS_0,1 provided from the mode register 100 or the first and second setting values PDC_0,1 and PDS_0,1 provided from the command decoder 400, based on the setting value EN associated with whether the mode register 100 is enabled.

For example, when the setting value EN associated with whether the mode register 100 is enabled is the first value (e.g., “1”), the multiplexer 500 may select the first and second setting values PDC_0,1 and PDS_0,1 provided from the mode register 100 so as to be provided to the power-down control circuit 200. For example, when the setting value EN associated with whether the mode register 100 is enabled is the second value (e.g., “0”), the multiplexer 500 may select the first and second setting values PDC_0,1 and PDS_0,1 provided from the command decoder 400 so as to be provided to the power-down control circuit 200.

The power-down control circuit 200 may control the power-down operation of the memory device 1100. For example, the power-down control circuit 200 may generate the control signal PD_ctrl for controlling the power-down operation and the start signal PD_start triggering the power gating operation, based on the PDE signal provided from the command decoder 400 and the first and second setting values PDC_0,1 and PDS_0,1 provided from the multiplexer 500. The power-down control circuit 200 may control the power-down operation of the memory device 1100 by controlling operations of the plurality of function blocks 310-1 to 310-x through the control signal PD_ctrl and the start signal PD_start.

How the power-down control circuit 200 generates the control signal PD_ctrl and the start signal PD_start and controls operations of the plurality of function blocks 310-1 to 310-x through the generated signals is described in detail with reference to FIGS. 5 to 11, and thus, additional description will be omitted to avoid redundancy.

According to the embodiment of FIG. 15, the memory controller 1200 may control the power-down operation of the memory device 1100 by selectively using one of the mode register 100 and the first command.

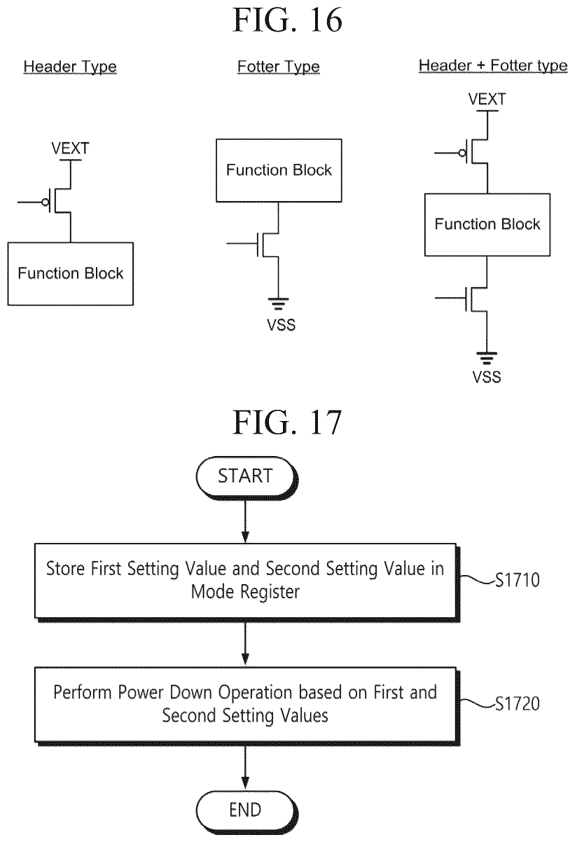

FIG. 16 is a diagram illustrating power gating switches according to one or more embodiments of the present disclosure.

In embodiments of the present disclosure, the power gating operation may refer to an operation of blocking an external power being provided to a function block targeted for the power gating operation. To this end, the power gating switch may be present between the corresponding function block and the external power or between the corresponding function block and the ground. In this case, the power gating switch present between the external power and the corresponding function block may be referred to as a “header type”, and the power gating switch present between the corresponding function block and the ground may be referred to as a “footer type”.

Referring to FIG. 16, the header-type power gating switch or the footer-type power gating switch may be used to perform the power gating operation on the function block, and the header-type power gating switch and the footer-type power gating switch may be used together to perform the power gating operation on the function block.

The cases where the header-type power gating switch is used are illustrated in FIGS. 8 through 11, but this is provided only as an example, and the disclosure is not limited thereto. According to one or more embodiments, it may be well understood that the footer-type power gating switch is used to perform the power gating operation on the function blocks 310-1 to 310-x or the header-type power gating switch and the footer-type power gating switch are used together to perform the power gating operation on the function blocks 310-1 to 310-x.

The case where the header-type power gating switch is implemented with a PMOS transistor and the footer-type power gating switch is implemented with an NMOS transistor is illustrated in FIGS. 8 through 11 and 16 as an example, but the present disclosure is not limited thereto. According to one or more embodiments, the NMOS transistor may be used as the header-type power gating switch, and the PMOS transistor may be used as the footer-type power gating switch; in this case, a particular method of determining whether to activate control signals for controlling operations of the power gating switches may vary depending on the modified/changed implementation example.

FIG. 17 is a flowchart illustrating an operating method a memory device according to one or more embodiments of the present disclosure. In FIG. 17, the description which is given above will be omitted or simplified.

Referring to FIG. 17, in operation S1710, the memory device 1100 may store the first setting value corresponding to the power-down operation to be performed in the power-down state and the second setting value corresponding to the start time of the power gating operation in the mode register 100.

For example, the memory controller 1200 may transmit the third command described above to the memory device 1100. Accordingly, the memory device 1100 may store the first setting value and the second setting value in the mode register 100 based on the third command thus received.

In operation S1720, the memory device 1100 may perform the power-down operation based on the first and second setting values.

For example, the memory device 1100 may enter the power-down state based on the first command described above. In the power-down state, the memory device 1100 may perform the power-down operation corresponding to the first setting value. In this case, when the power-down operation corresponding to the first setting value includes the power gating operation, the memory device 1100 may perform the power gating operation at the start time corresponding to the second setting value after entering the power-down state.

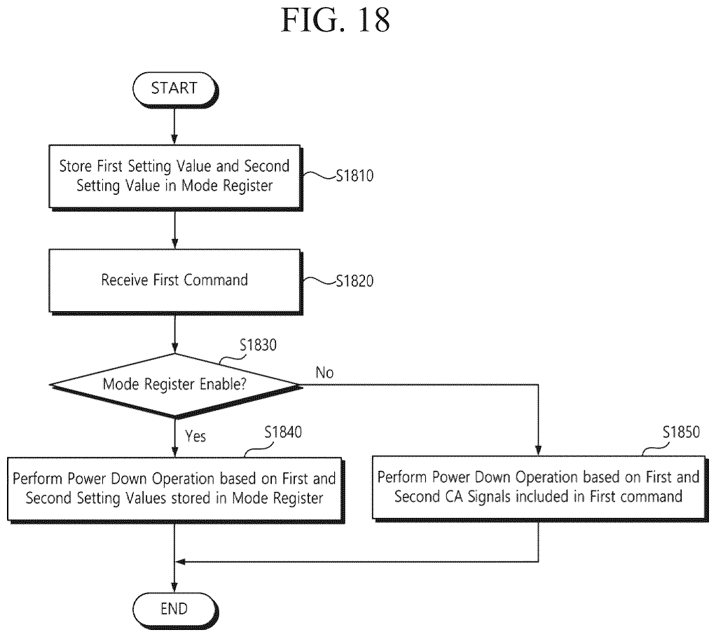

FIG. 18 is a flowchart illustrating an operating method a memory device according to one or more embodiments of the present disclosure. In FIG. 18, the description which is given above will be omitted or simplified.

Referring to FIG. 18, in operation S1810, the memory device 1100 may store the first setting value and the second setting value in the mode register 100. Operation S1810 may correspond to operation S1710 of FIG. 17.

In operation S1820, the memory device 1100 may receive the first command from the memory controller 1200. The first command may be the PDE command or the SRE command.

In operation S1830, the memory device 1100 may determine whether the mode register 100 is enabled. For example, when the setting value of the enable field of the mode register 100 is the first value (e.g., “1”), the memory device 1100 may determine that the memory device 1100 is enabled. Also, when the setting value of the enable field of the mode register 100 is the second value (e.g., “0”), the memory device 1100 may determine that the memory device 1100 is disabled.

When the mode register 100 is enabled (Yes in operation S1830), the memory device 1100 may perform operation S1840. In operation S1840, the memory device 1100 may perform the power-down operation based on the first and second setting values stored in the mode register 100.

When the mode register 100 is disabled (No in operation 1830), the memory device 1100 may perform operation S1850. In operation S1850, the memory device 1100 may perform the power-down operation based on the first command/address signal and the second command/address signal included in the first command. In this case, the first command/address signal and the second command/address signal may respectively correspond to the first setting value and the second setting value.

According to the embodiments of the present disclosure described above, the power-down operation of the memory device may be variously controlled by the memory controller. Accordingly, optimization of a system power may be accomplished.

At least one of the components, elements, modules, units, or the like (collectively “components” in this paragraph) represented by a block or an equivalent indication (collectively “block”) in the above embodiments including the drawings such as FIGS. 1, 4, 5, 7, 9-11, and 14-16, for example, memory controller, peripheral circuits, mode registers, the power-down control circuit, decoders, function blocks, oscillator, counter, multiplexers, controller, counter, gates, switches, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

While the present disclosure has been described with reference to one or more embodiments thereof, it will be apparent to those of ordinary skill in the art that various changes and modifications may be made thereto without departing from the spirit and scope of the present disclosure as set forth in the following claims.

What is claimed is:

1. A memory device comprising:
a mode register configured to store a first setting value corresponding to a power-down operation to be performed in a power-down state and a second setting value corresponding to a start time of a power gating operation; and
a power-down control circuit,
wherein the power-down control circuit is configured to:
control the memory device to perform the power-down operation based on a first command for causing the memory device to enter the power-down state, and
based on the power-down operation comprising the power gating operation, control the memory device to perform the power gating operation at the start time after the memory device enters the power-down state.

2. The memory device of claim 1,
wherein the first setting value is one of a plurality of values respectively corresponding to a plurality of power-down operations,
wherein the plurality of power-down operations comprise:
a first power-down operation comprising turning off an input/output buffer among a plurality of function blocks of the memory device; and
a second power-down operation comprising the first power-down operation and a power gating operation for a function block belonging to a first group from among the plurality of function blocks,
wherein the first power-down operation corresponds to a first value among the plurality of values, and
wherein the second power-down operation corresponds to a second value among the plurality of values.

3. The memory device of claim 2, wherein the power-down control circuit is further configured to, based on the first setting value being the first value, turn off the input/output buffer and ignore the second setting value.

4. The memory device of claim 2, wherein the power-down control circuit is further configured to, based on the first setting value being the second value, turn off the input/output buffer and block external power from being provided to the function block belonging to the first group at the start time.

5. The memory device of claim 2,
wherein the plurality of power-down operations further comprise:
a third power-down operation comprising the first power-down operation and a power gating operation for a function block belonging to a second group from among the plurality of function blocks,
wherein the second group comprises the function blocks of the first group and a function block not belonging to the first group, and
wherein the third power-down operation corresponds to a third value among the plurality of values.

6. The memory device of claim 5, wherein the power-down control circuit is further configured to, based on the first setting value being the third value, turn off the input/output buffer and block external power from being provided to the function blocks belonging to the second group at the start time.

7. The memory device of claim 5,
wherein the power gating operation of the third power-down operation is performed based on a cut-off voltage of a first level,
wherein the plurality of power-down operations further comprise:
a fourth power-down operation comprising the first power-down operation and a power gating operation based on the cut-off voltage of a second level for the function block belonging to the second group, and
wherein the fourth power-down operation corresponds to a fourth value among the plurality of values.

8. The memory device of claim 7, wherein the power-down control circuit is further configured to, based on the first setting value being the fourth value, turn off the input/output buffer and block external power from being provided to the function block belonging to the second group based on the cut-off voltage of the second level at the start time.

9. The memory device of claim 1,
wherein the start time is a predetermined time after the memory device enters the power-down state,
wherein the second setting value is one of a plurality of values respectively corresponding to a plurality of predetermined times, and
wherein the plurality of predetermined times are integer multiples of a reference time.

10. The memory device of claim 9, wherein the reference time is a period of an output signal of an oscillator operating in the power-down state.

11. The memory device of claim 1,
wherein the mode register stores the first setting value and the second setting value based on a second command received from a memory controller, and
wherein the second command comprises the first setting value and the second setting value.

12. The memory device of claim 1,
wherein the mode register comprises:
a power-down operation field configured to store the first setting value and the second setting value; and
an enable field configured to store a setting value associated with a state of enablement of the mode register, and
wherein the power-down control circuit is further configured to, based on the setting value of the enable field being a first value, control the power-down operation by using the first setting value and the second setting value.

13. The memory device of claim 12,
wherein the power-down control circuit is further configured to, based on the setting value of the enable field being a second value, control the power-down operation based on the first command, and
wherein the first command comprises first command/address signals corresponding to the first setting value and second command/address signals corresponding to the second setting value.

14. The memory device of claim 1, wherein, based on the memory device not being in the power-down state at the start time, the memory device does not perform the power gating operation.

15. The memory device of claim 7, wherein the power-down control circuit comprises:
a first decoder configured to decode the first setting value and to output one or more control signals for controlling the power-down operation;
a second decoder configured to decode the second setting value and to output a selection signal for selecting the start time;
an oscillator configured to output a clock signal based on the first command;
a counter configured to output a plurality of period signals associated with the start time based on the clock signal; and
a multiplexer configured to output a start signal to trigger the power gating operation based on the selection signal and the plurality of period signals.

16. The memory device of claim 15,
wherein the one or more control signals comprise:
a first control signal configured to turn off the input/output buffer;
a second control signal associated with the power gating operation for the function block belonging to the first group;
a third control signal associated with the power gating operation for the function block belonging to the second group; and
a fourth control signal configured to control a level of the cut-off voltage used in the power gating operation, and
wherein the first, the second, the third and the fourth power-down operations are implemented by a combination of the start signal and the first, the second, the third, and the fourth control signals.

17. A method of operating a memory device, the method comprising:
storing, in a mode register of the memory device, a first setting value corresponding to a power-down operation to be performed in a power-down state and a second setting value corresponding to a start time of a power gating operation; and
based on the memory device entering the power-down state, performing the power-down operation based on the first and the second setting values,
wherein the performing of the power-down operation comprises:
based on the power-down operation corresponding to the first setting value comprising the power gating operation, performing the power gating operation at the start time after the memory device enters the power-down state.

18. The method of claim 17,
wherein the mode register comprises:
a power-down operation field configured to store the first setting value and the second setting value; and
an enable field configured to store a setting value associated with a state of enablement of the mode register, and
wherein the performing the power-down operation further comprises:
based on the setting value of the enable field being a first value, performing the power-down operation by using the first and the second setting values.

19. The method of claim 18,
wherein the performing the power-down operation further comprises:
based on the setting value of the enable field being a second value, performing the power-down operation based on a command for entering the power-down state, and
wherein the command for entering the power-down state comprises first command/address signals corresponding to the first setting value and second command/address signals corresponding to the second setting value.

20. A memory system comprising:
a memory controller configured to transmit a mode register write command comprising a first setting value corresponding to a power-down operation and a second setting value corresponding to a start time of a power gating operation; and
a memory device comprising a mode register, wherein the memory device is configured to:
set the first setting value and the second setting value in the mode register based on the mode register write command,
to perform a power-down operation corresponding to the first setting value when a power-down entry command is received from the memory controller, and
based on the power-down operation comprising the power gating operation, perform the power gating operation at the start time after the memory device enters a power-down state.
